(19) United States
(12) Patent Application Publication
(10) Pub. No.: US 2006/0043577 A1
(43) Pub. Date: Mar. 2, 2006

(54) Structure and process of semiconductor package with an exposed heatsink

(76) Inventor: Chih-An Yang, Hsin Tien City (TW)

Correspondence Address: BIRCH STEWART KOLASCH & BIRCH, PO BOX 747, FALLS CHURCH, VA, 22040-0747, US

(21) Appl. No.: 10/983,699

(22) Filed: Nov. 9, 2004

(30) Foreign Application Priority Data
Aug. 31, 2004 (TW) 93126253

(51) Int. Cl. H01L 23/34

(52) U.S. Cl. 257/706

(57) ABSTRACT

A structure and a process of semiconductor package with an exposed heatsink not only reduces the mold-clamping force acted on the chip but also improves the heat-dissipation by the heatsink directly adhered on the chip. Furthermore, the reliability of the semiconductor package is also improved. The structure of semiconductor package comprises a substrate, a chip disposed on the substrate, a heatsink with a bottom surface adhered to the top surface of the chip, and an encapsulation material over the substrate, the chip and part of the lateral side of the heatsink, wherein the top end of the lateral side of the heatsink is higher than the encapsulation material at least 0.05 mm.

### BACKGROUND OF THE INVENTION

1. Field of the Invention

The present invention is related to a structure and a process of semiconductor package, especially to a semiconductor package with an exposed heatsink to improve heat-dissipation and reliability of the semiconductor package.

2. Description of Related Art

The structure of a BGA (Ball Grid Array) semiconductor package provides enough input and output (I/O) pins to meet the demands of a great number of electrical components inside the chip and a high density of integrated circuits.

However, a plurality of conductive wires is needed for the BGA semiconductor package to connect the active surface of the chip with a substrate under the chip, wherein the active surface is on the top side of the chip. Because the electric signal transmissions between the chip and the substrate are extended, it is not applicable for the package of high-speed elements. Otherwise, the size of the chip package will be enlarged due to the space to form the conductive wires. Furthermore, in order to prevent the chip damage due to the force made by the process of injecting the encapsulation material, the heatsink is not directly adhered to the chip of the BGA package. Additionally, the thermal conductivity of the encapsulation material is low. Thus, the heat dissipation efficiency of the semiconductor package is not well promoted.

To solve the above-mentioned disadvantages, a prior art shown in FIG. 1 provides a heat-dissipating structure for semiconductor package which comprises a heatsink 4a, a thermal-conductive spacer 5a, and a flexible adhesive layer 6a. The heatsink 4a includes an exposed surface without the encapsulation material 9a of the semiconductor package and another surface adhered to the upper surface of the spacer 5a. The top surface of the flexible adhesive layer 6a adhered to the lower surface of the spacer 5a, and the bottom surface of the flexible adhesive layer 6a further adhered to a chip 3a of the semiconductor package.

Although, the thermal-conductive spacer transfers the heat generated by the chip to the heatsink and enhances the mechanical strength of the chip, the height of the package is increased inevitably and the heat-dissipation may be insufficient due to the chip is not attached the heatsink directly.

The flip chip technique is an advanced technology for the semiconductor packaging. The major characteristic of the flip chip technique is to turn the chip over on the substrate, i.e. the active surface faces to the substrate. Meanwhile, a plurality of solder bumps on the active surface are electrically connected to the substrate, and an underfill technique is used to inject the insulation material among the solder bumps for connecting the semiconductor chip with the substrate firmly. Because the flip chip semiconductor package does not use the conductive wires which occupy too much space, the dimension of package is reduced for size-shrinking needing of semiconductors. FCBGA (Flip Chip Ball Grid Array) package includes a chip with active surface faced down on the substrate and a plurality of ball-like solders, instead of pins, as the connections between the chip and the substrate.

Please refer to an invention shown in FIG. 2A, a semiconductor package structure using the flip chip technique comprising a substrate 10a, a chip 12a disposed on the substrate 10a using the flip chip method, an insulation material 14a is filled between the chip and the substrate, and a heatsink 16a adhered to the chip 12a by a thermal-conductive material 18a. The prior art provides a structure with exposed heatsink adhered on the chip to improve the thermal performance. However, the insulation material 14a is expensive and needs a long time to cure when processing. Furthermore, moisture can damage the chip and reduce the reliability of the chip because the chip is not well encapsulated.

To improve the problem of the reliability in the abovementioned prior art, another invention shown in FIG. 2B puts a chip 22a on the substrate 20a and fills the chip 22a with the insulation material 24a. Then, an encapsulation material 26a which can prevent electromagnetic interference seals the chip 22a to ensure the reliability of the chip. However, the heat-dissipating problem may occur.

Another invention of a flip chip package to improve heat-dissipating problem is showed in FIG. 3C. The chip 31a is disposed on the substrate 30a using the flip chip method and electrically connected to the substrate 30a by solder bump 32a. Between the chip 31a and the substrate 30a is a gap filled with an insulation material 33a. A dam 303a of the adhesive material is formed at the outer area of the chip 31a on the substrate 30a, wherein the thermal expansion coefficient of the adhesive material is larger than that of the substrate 30a. Further, the encapsulation material 35a covers the chip 31a, and a heatsink 36a is disposed within the encapsulation material.

However, the clamping force of the mold during the encapsulation material 35a injection is about 30 tons, but the stress that the chip can suffered is only from 100 to 150 kilograms. Therefore, the heatsink 36a is not in contact with the chip 31a, and a gap between them is preserved to prevent damage of the chip 31a caused by the stress from the mold-clamping. However, heat generated by the chip may not be transferred to the heatsink because of the gap.

Therefore, it is desirable to provide a semiconductor package of good heat dissipation without the loss of reliability.

### SUMMARY OF THE INVENTION

The present invention provides a structure and a process of semiconductor package with an exposed heatsink to improve the thermal dissipation and the reliability of the semiconductor package.

The structure of the semiconductor package comprises a chip electrically connected to a substrate and a heatsink directly adhered on the chip. The encapsulation material seals the chip and a part of the lateral side of the heatsink, wherein the top end of the lateral side is higher than the encapsulation at least 0.05 mm.

The process of the semiconductor package with an exposed heatsink comprises the following steps: providing a semiconductor assembly which comprises a substrate, a chip electrically connected to the substrate, and a heatsink adhered to the chip; providing a mold disposed the semiconductor assembly to form a receiving cavity and a gap between the mold and the top surface of the heatsink, wherein a top surface of the receiving cavity is lower than the top end of the lateral side of the heatsink at least 0.05 mm; injecting encapsulation material into the receiving cavity of the mold.

According to the above-mentioned structure and the process, the semiconductor package provides the full encapsulation to protect the chip and an exposed heatsink to transfer the heat generated by the chip. Therefore, the reliability of the semiconductor package is improved.

### BRIEF DESCRIPTION OF THE DRAWINGS

FIG. 1 shows a cross-sectional view of a BGA semiconductor package structure according to the prior art.

FIG. 2A shows a cross-sectional view of a flip chip package structure according to the prior art.

FIG. 2B shows a cross-sectional view of another flip chip package structure according to the prior art.

FIG. 2C shows a cross-sectional view of the semiconductor package structure to improve heat-dissipation according to the prior art.

FIG. 3 shows a cross-sectional view of the semiconductor package structure according the first embodiment of the present invention.

FIG. 4 shows a cross-sectional view of the semiconductor package in the mold clamping step according to the first embodiment of the present invention.

FIG. 4A shows a cross-sectional view of a partial amplifying diagram of FIG. 4.

FIG. 5 shows a cross-sectional view of the semiconductor package in the injecting encapsulation step according to the first embodiment of the present invention.

FIG. 5A shows a top view of the semiconductor package structure according to the first embodiment of the present invention.

FIG. 6 shows a cross-sectional view of the semiconductor package structure covered with encapsulation according to the first embodiment of the present invention.

FIG. 7 shows a cross-sectional view of the semiconductor package structure according to the second embodiment of the present invention.

FIG. 8 shows a cross-sectional view of the semiconductor package structure according to the third embodiment of the present invention.

FIG. 9 shows a cross-sectional view of the semiconductor package structure according to the fourth embodiment of the present invention.

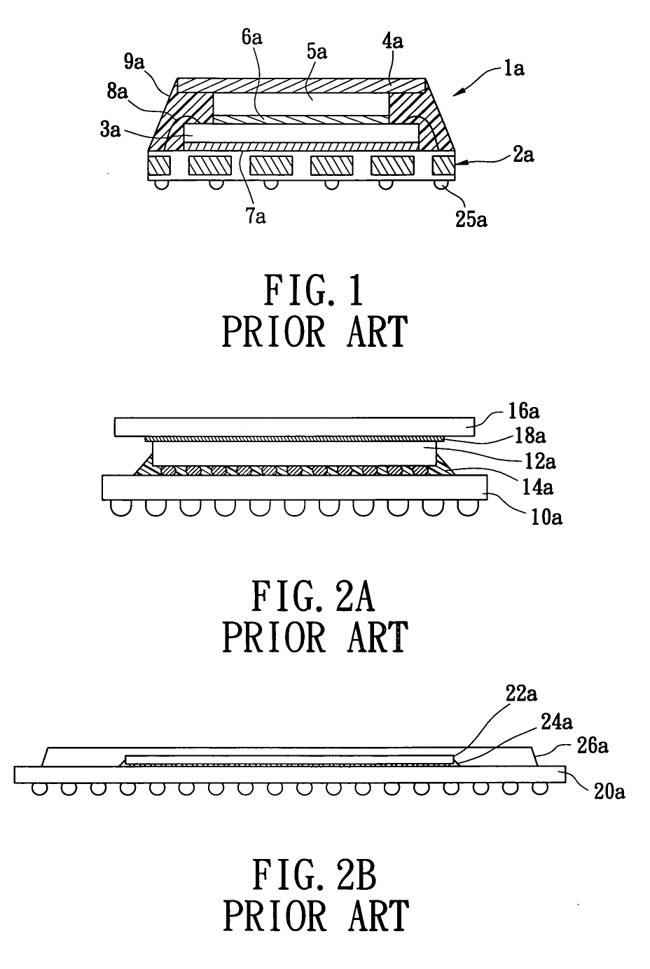

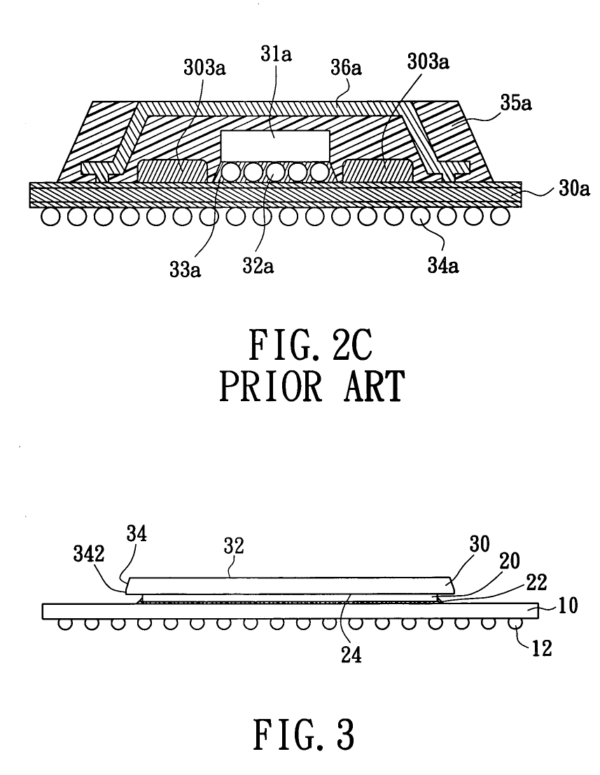

### DETAILED DESCRIPTION OF PREFERRED EMBODIMENTS

The present invention is a semiconductor package providing good heat-dissipation, reducing the mold-clamping stress to prevent the chip damage, and promoting the reliability.

FIGS. 3 to 6 show the packaging process according to the embodiment of the present invention in flip chip technique. The packaging process comprises the following steps: providing a semiconductor assembly, providing a mold disposed at least one said semiconductor assembly, and injecting encapsulation material into the mold.

At the step “providing a semiconductor assembly”, the semiconductor assembly comprising: a substrate 10, a chip 20 electrically connected to the substrate 10, and a heatsink 30 adhered to a top surface of the chip 20. In this embodiment shown in FIG. 3, the flip chip method is used in the connection between the chip 20 and the substrate 10, and the underfill technique is used to inject an insulation material 22 among the chip 20 and the substrate 10 for secure connection between them.

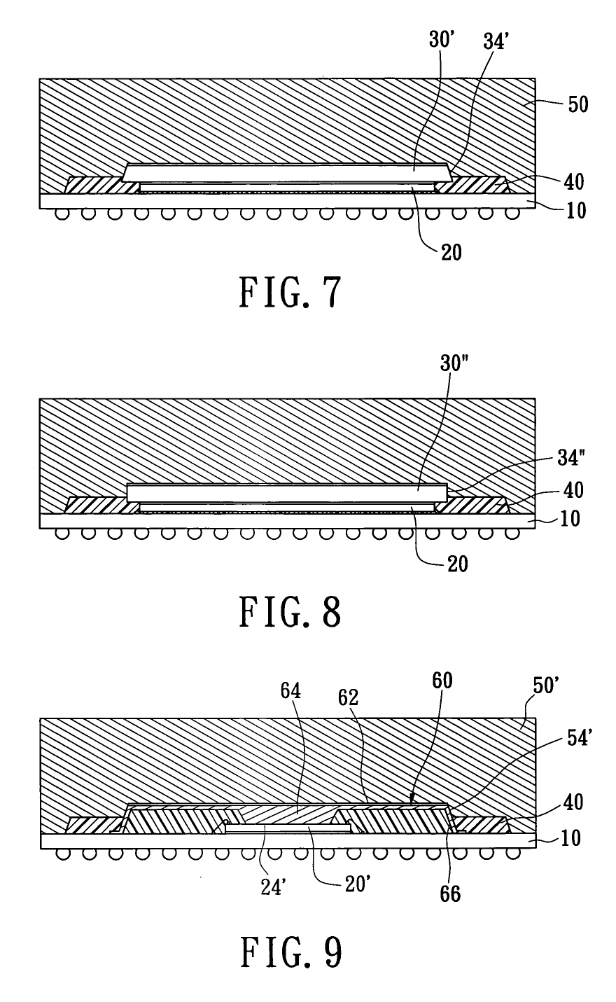

The heatsink 30 in the preferred embodiment is sheet-like with a lateral side 34 consisting of an inclined plane and a vertical surface 342 extended downward from the inclined plane. Moreover, the variations and modifications of the heatsink will be made by those skilled in the art. For example, an embodiment shown in FIG. 7 includes a heatsink 30′ which the lateral side 34′ is inclined, and the third embodiment shown in FIG. 8 includes a heatsink 30″ which the lateral side 34″ is vertical. Furthermore, the inclined plane in the lateral side of the heatsink provides the function of self-alignment when the mold chase closing.

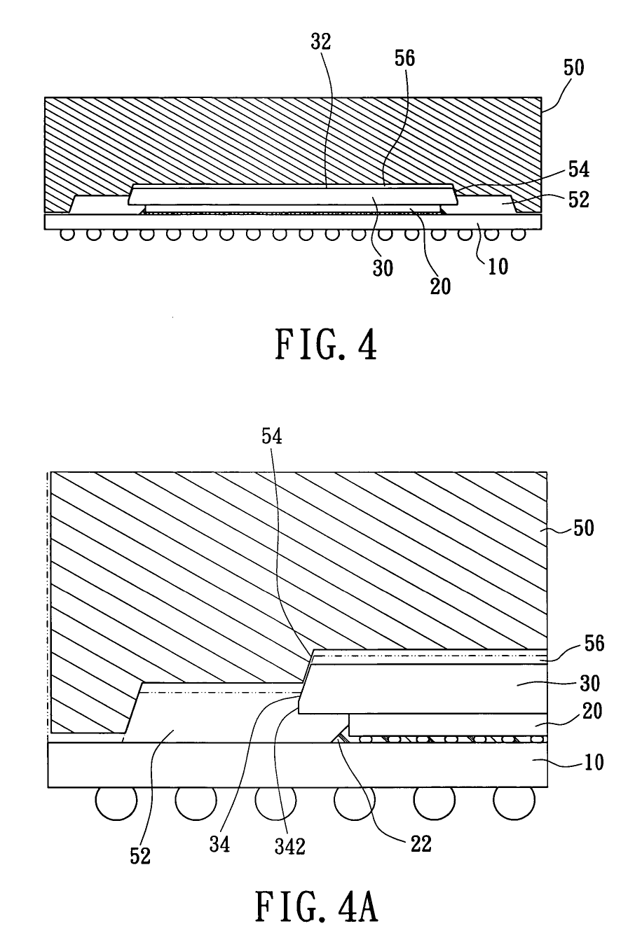

The step “proving a mold” is to provide a mold 50 with a concave mold cavity for injecting the encapsulation material to seal the chip. Referring to FIG. 4, when the mold 50 moves downward, a matched plane 54 inside the mold cavity of the mold 50 fits the lateral side 34 of the heatsink 30. Thus, a receiving cavity for encapsulation 52 and a gap 56 between the mold 50 and the top surface of the heatsink 30 are formed. The top surface of the receiving cavity for encapsulation 52 is lower than the top surface 32 of the heatsink 30 at least 0.05 mm. Furthermore, the clamping force of the mold 50 acted on the heatsink 30 is reduced by the gap 56 because the clamping force is not directly acted on the chip 20 and is only distributed on the substrate 10 and around the heatsink 30.

Please refer to FIG. 4A, which enlarges a part of FIG. 4. During the semiconductor packaging process, the mold 50 is difficult to align with the semiconductor assembly and mismatches between them often occur. Moreover, the semiconductor assembly may be shift due to the vibration, thus a reliable alignment of the semiconductor assembly and the mold is necessary to ensure the proper encapsulation. In this embodiment, the inclined plane of the lateral side 34 of the heatsink 30 and the matched plane 54 inside of the cavity of the mold 50 would guide the mold 50 to the correct position during the mold chase closing. Furthermore, the circular heatsink 30 is one preferred embodiment of the present invention to reduce the mismatches between the semiconductor assembly and the mold cavity.

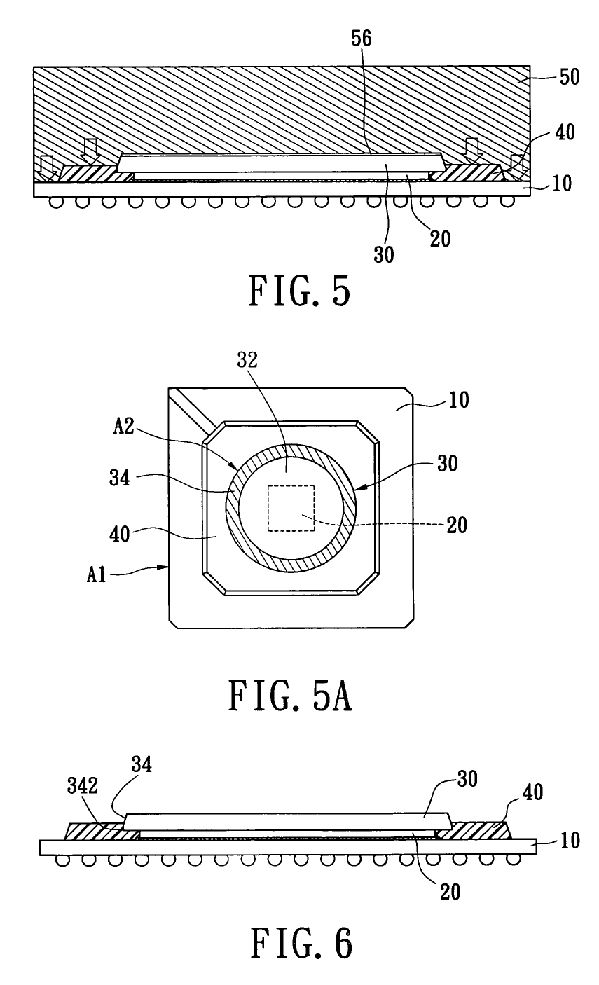

FIG. 5 shows the step of injecting encapsulation material into the mold. After the mold 50 guided to the correct position with respect to the semiconductor assembly, the encapsulation material 40 is injected to the receiving cavity 52. After forming the encapsulation material, the structure of the present invention is completed, as shown in FIG. 5A and FIG. 6. Referring to the vertical view of the embodiment of the present invention show in FIG. 5A, the semiconductor package with an exposed heatsink comprises the base plate 10, the chip 20, the heatsink 30 and the encapsulation material 40, wherein the exposed top surface of the heatsink 30 is higher than the encapsulation material 40 at least 10% of the height of the encapsulation material 40 and at least 0.05 mm.

The gap 56 is preserved between the mold 50 and the semiconductor assembly, and the clamping force made by the mold 50 is mainly distributed on the substrate 10, the encapsulation material 40, and around the lateral side 34 of the heatsink 30. Hence, the present invention effectively reduces the clamping force made by the mold 50 acted on the chip 20. Supposing the projected horizontal area of the semiconductor assembly is A1, the projected horizontal area of the inclined plane of lateral side 34 of the heatsink 30 is A2, and the clamping force of the mold 50 is F, the force F2 acted on the heatsink is F*A2/(A2+A1) and is smaller than the clamping force F.

The above-mentioned process shows a preferred embodiment of the present invention using the flip chip method for semiconductor package. Moreover, the present invention can be used in the mold clamping step in other semiconductor packaging. FIG. 9 shows a chip 20′ electrically connected to the substrate 10 by conductive wires and a heatsink 60. The heatsink 60 further includes a base 62, and a convex part 64 protruded downward from the base and adhered a part of the top surface 24′ of the chip 20′. There is a gap existing between the mold 50′ and the top surface of the heatsink 60. The heatsink 60 further includes a supporting part 66 inclined downward from the edge of the base 62 and attached the substrate 10. Additionally, the preferred embodiment of heatsink 60 is circular and has an inclined sidewall. The matched plane 54′ in the cavity of the mold 50′ is fit for the inclined plane of the heatsink 60.

The characteristics and functions of the present invention are summarized as following:

1. The present invention reduces the mold-clamping force acted on the chip during the encapsulation injection and prevents the damage of the chips.

2. The heatsink is exposed outside of the encapsulation material and contacts the chip to improve the heat-dissipating ability of the package. Furthermore, the encapsulation material fully seals the chip to prevent the chip from the damage by moisture, and to increase the reliability and the life time of the chip.

3. The heatsink of the present invention provides an aligning function for molding chase closing to reduce the mismatches between the mold and the chips.

Although the present invention has been described in relation to particular embodiments thereof, many modifications and variations will become apparent to those skilled in the art. Therefore, the present invention is not limited by the specific disclosure herein.

What is claimed is:

1. A semiconductor package structure with an exposed heatsink, comprising:
a substrate;
a chip disposed on a top surface of the substrate;
a heatsink with a bottom surface adhered to a top surface of the chip; and
an encapsulation material over the substrate, the chip and a part of a lateral side of the heatsink, wherein a top end of the lateral side protrudes from the encapsulation material at least 0.05 mm.

2. The semiconductor package structure of claim 1, wherein the chip is electrically connected to the substrate using the flip chip technique.

3. The semiconductor package structure of claim 2, wherein the heatsink is sheet-like.

4. The semiconductor package structure of claim 3, wherein the lateral side of the heatsink is a vertical plane.

5. The semiconductor package structure of claim 3, wherein the lateral side of the heatsink is an inclined plane.

6. The semiconductor package structure of claim 3, wherein the lateral side of the heatsink includes an inclined plane and a vertical plane extended downward from the inclined plane.

7. The semiconductor package structure of claim 1, wherein the chip is electrically connected to the substrate with conductive wires.

8. The semiconductor package structure of claim 7, wherein the heatsink includes a base, and a convex part protruded downward from of the base and adhered to the top surface of the chip.

9. The semiconductor package structure of claim 8, wherein the heatsink further includes a supporting part which is an inclined extension from the edge of the base to the substrate.

10. A semiconductor package process with an exposed heatsink comprising:
providing a semiconductor assembly comprising a substrate, a chip electrically connected to the substrate, and a heatsink adhered to a top surface of the chip;
providing a mold disposed at the semiconductor assembly to form a receiving cavity for encapsulation and a gap between a top surface of the heatsink and the mold, wherein a top surface of the receiving cavity is lower than a top end of a lateral side of the heatsink at least 0.05 mm; and
injecting encapsulation material into the receiving cavity of the mold.

11. The semiconductor package process of claim 10, wherein the chip is electrically connected to the substrate using the flip chip technique.

12. The semiconductor package process of claim 11, wherein the heatsink is sheet-like.

13. The semiconductor package process of claim 12, wherein the lateral side of the heatsink is a vertical plane.

14. The semiconductor package process of claim 12, wherein the lateral side of the heatsink is an inclined plane.

15. The semiconductor package process of claim 12, wherein the lateral side of heatsink includes an inclined plane and a vertical plane extended downward from the inclined one.

16. The semiconductor package process of claim 10, wherein the chip is electrically connected to the substrate with conductive wires.

17. The semiconductor package process of claim 16, wherein the heatsink includes a base, and a convex part protruded downward from the bottom of the base and adhered to the top surface of the chip.

18. The semiconductor package process of claim 17, wherein the heatsink further includes a supporting part which is an inclined extension downward from the edge of the base to the substrate.
